(19) United States
(12) Patent Application Publication
(10) Pub. No.: US 2006/0139890 A1
(43) Pub. Date: Jun. 29, 2006

(54) Fastening device II

(76) Inventor: A-Sheng Liu, Shu Lin City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/019,174

(22) Filed: Dec. 23, 2004

(51) Int. Cl. H05K 7/20

(52) U.S. Cl. 361/719

(57) ABSTRACT

A fastening device II has a body and four fixed handles. The body is integrated with a frame, extending arms, elastic hooking arms, and linking-up arms. The fixed handles respectively have an eccentric wheel pivotally connected with the linking-up arm of the body. One of the eccentric wheels respectively forms a fixed section and a released section on the edge thereof and the fixed section and the released section selectively connects with the contacting surface of the body. Thereby, the fastening device II has a simplified structure, a simple fabrication process, reduced production costs, a stable structure, and a strong clipping strength.

### BACKGROUND OF THE INVENTION

1. Field of the Invention

The present invention relates to a fastening device II, and more particularly to a fastening device that rigidly presses a radiator on a central processing unit. The fastening device has a simplified structure, a simple fabrication process, reduced production costs, a stable structure, and a strong clipping strength.

2. Description of the Prior Art

A central processing unit (CPU) is the heart of the computer and deals with information sent from different devices. The information is sent to the correct device according to computer instructions after determining and calculating the information. Because the computer industry has advanced at an astounding speed, the heat generated by a CPU is increasingly higher as the size of the CPU is increasingly smaller. In order to dissipate effectively CPU-generated heat, thereby allowing maintenance of normal CPU operations at an allowed temperature, a radiator with a larger area is usually disposed on the surface of the CPU. The radiator dissipates to dissipate the heat from the CPU so as to maintain operations and extend the life of the CPU.

In order to dispose firmly the CPU on the motherboard, it is necessary to install a fastening device. According to Taiwan Patent No. TW573922 (application number 92210398), a fastening device is applied to a locked component 80 disposed on the motherboard 81. The locked component 80 has locating holes 82 corresponding to the fastening device and a plurality of through holes 83 correspondingly drilled in the motherboard 81.

The fastening device comprises a plurality of fixed shafts 84 passing through the locating holes 82 and the through holes 83. The fixed shafts 84 have pivoted portions 85 disposed at the top of the fixed shafts 84, constricted sections 86 installed in the through holes 83, and protruded portions 87 disposed at the bottom of the fixed shafts 84. The pivoted portions 85 are disposed on the locating holes 82 and the protruded portions 87 are installed below the through holes 83. Operating bodies 88 pivotally connected with the top of the fixed shafts 84 and the operating bodies 88 have eccentric rolling bodies 89, eccentric shafts 90 installed in the rolling bodies 89 and pivotally connected with the pivoted portions 85 of the fixed shafts 84, and pressing arms 91 protruding from the eccentric rolling bodies 89. Springs 92 are installed on the upper half of the fixed shafts 84 and located below the locked component 80. Fragments 93 are U-type, downward installed at the lower half of the fixed shafts 84 and located below the springs 92. Two ends of the fragments 93 inwardly fold two clamping portions 94 and the clamping portions 94 are symmetrically located in the through holes 83 to t rigidly ouch the constricted sections 86 of the fixed shafts 84.

To sum up, the fastening device of the prior art comprises a locked component 80 and four fastening devices. Each of the fastening devices respectively has a fixed shaft 84, an operating body 88, a spring 92, and a fragment 93, hence requiring assembly of many parts and resulting in a structure that is not only unstable structure but also expensive. Moreover, there is a positioning question because the fixed shafts 84 need to pass one by one through the through holes 83 of the motherboard 81 and the motherboard 81 is easily damaged by the fragments 93 rigidly touching thereon.

### SUMMARY OF THE INVENTION

It is prime objective of the present invention to provide a fastening device with and integrated design, a small number of components, a simplified structure, a simple fabrication process, reduced production costs, a stable structure, and a strong clipping strength so that the fastening device is disposed on a motherboard without mismatching and or damage to the motherboard.

For achieving the objective stated above, a fastening device II comprises the following elements. A body has a frame with four corners, with each of the corners of the frame respectively extending a extending arm. The extending arm has a top with a contacting surface and one end of the extending arm extends an elastic hooking arm. Two sides of the elastic hooking arm connect with linking-up arms. Four fixed handles respectively have a handle body, one end of the handle body connects with a pressing arm and the other end of the handle body connects with a eccentric wheel. The eccentric wheels of the fixed handles pivotally connect with the linking-up arms of the body. One of the eccentric wheels respectively forms a fixed section. A released section on the edge thereof, the fixed section and the released section selectively connect with the contacting surface of the body.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 is a perspective exploded view of a fastening device of the prior art;

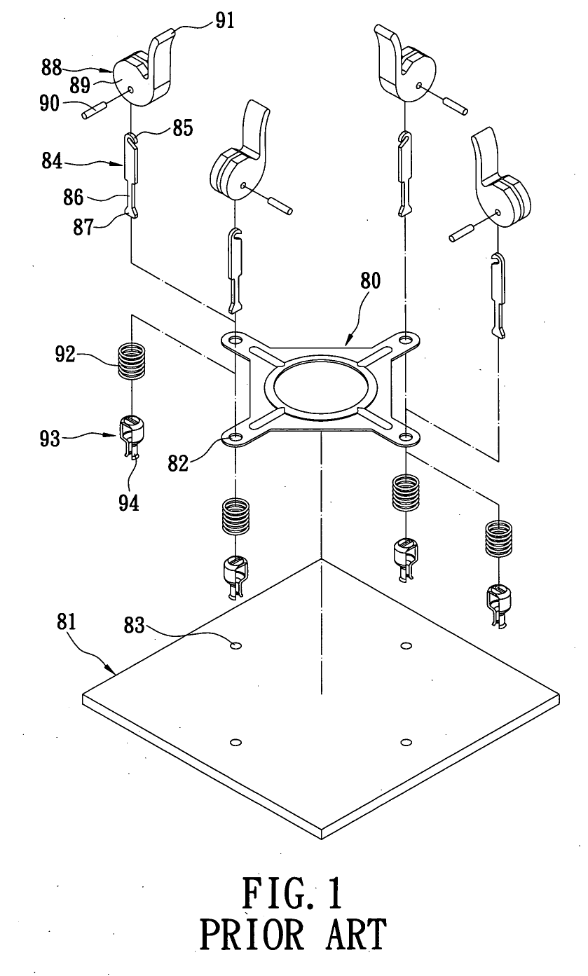

FIG. 2 is a perspective exploded view of a fastening device of the present invention;

FIG. 3 is a perspective view of a fastening device of the present invention;

FIG. 4 is a front view of a fastening device of the present invention;

FIG. 5 is a schematic view I of a fastening device of the present invention in use; and

FIG. 6 is a schematic view II of a fastening device of the present invention in use.

### DETAILED DESCRIPTION OF THE PREFERRED EMBODIMENTS

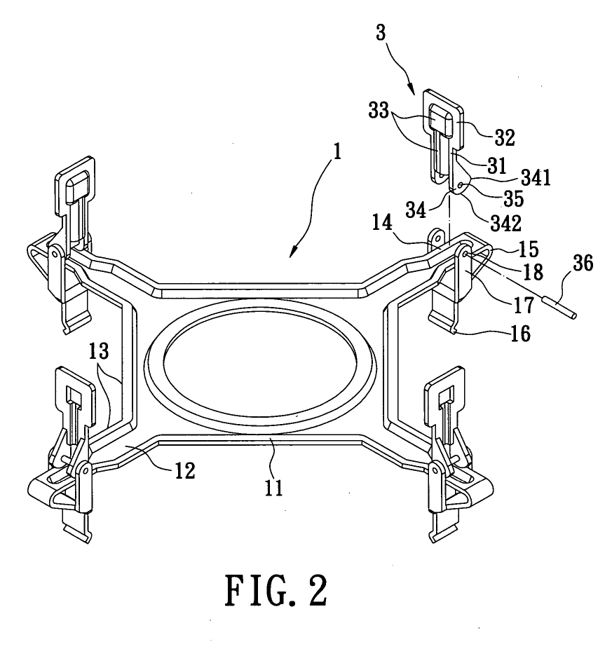

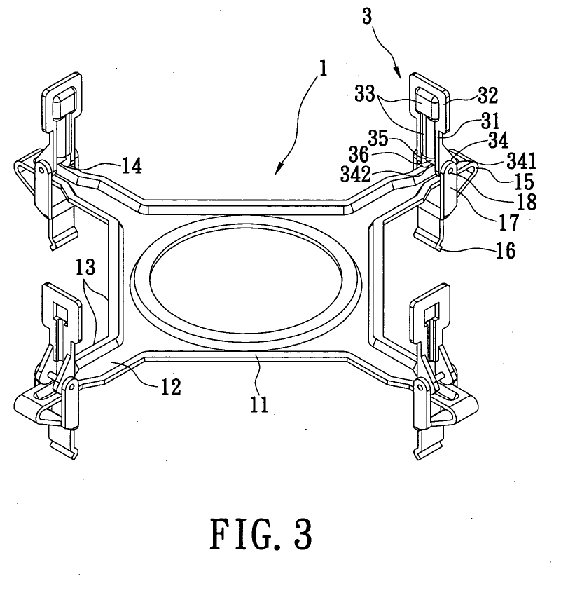

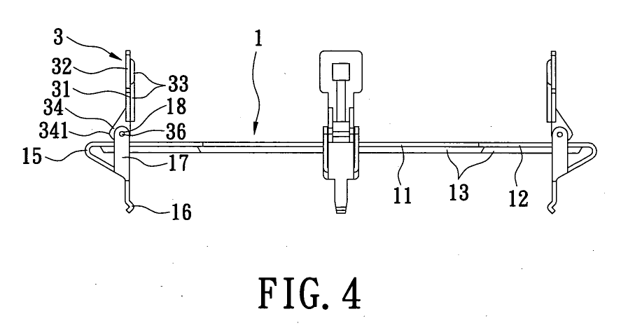

Reference is made to FIG. 2, FIG. 3, and FIG. 4. The present invention provides a fastening device II, and more particularly a fastening device rigidly pressing a radiator on a central processing unit. A fastening device II comprises a body 1 and four fixed handles 3. The body 1 is an integrated structure made of metal materials with good elasticity. The body 1 has a hollow rectangular frame 11 and the frame 11 has four corners; each of the corners of the frame 11 respectively extends an extending arm 12. The frame 11 of the body 1 and the edge of the extending arms 12 form strengthening portions 13 for increasing the strength of the body 1. The extending arm 12 has a top with a contacting surface 14 and one end of the extending arm 12 forms a free end; the free end downward extends an elastic hooking arm 15 with an elastic hooking function and the bottom of the elastic hooking arm 15 forms a hook-typed hooking portion 16. Two sides of the elastic hooking arm 15 connect with auricular linking-up arms 17 and the linking-up arms 17 are not only vertically upward extended to suitable height but changed to various angles of inclination. Each of the linking-up arms 17 of the body 1 respectively drills a pivoted hole 18 for linking the elastic hooking arm 15 to swing inwardly and outwardly while the linking-up arms 17 driven.

The fixed handles 3 are manufactured from metal material and each of the handles 3 respectively has a handle body 31 with suitable length. One end of the handle body 31 connects with a pressing arm 32 and the handle body 31 and the pressing arm 32 have middles protrudingly forming a strengthening portion 33 for increasing the strength of the fixed handles 3; two sides of the other end of the handle body 31 respectively connects with a eccentric wheel 34 and each of the eccentric wheels 34 of the fixed handles 3 respectively drills a shaft hole 35 that corresponds to the pivoted hole 18. One of the eccentric wheels 34 respectively forms a fixed section 341 and a released section 342 on the edge thereof and a distance from the fixed section 341 to the shaft hole 35 of the eccentric wheel 34 of the fixed handle 3 is greater than a distance from the released section 342 to the shaft hole 35 thereof.

The shaft holes 35 of the fixed handles 3 pivotally connect with the pivoted holes 18 of the linking-up arms 17 of the body 1 via a plurality of pivots 36 so that the eccentric wheels 34 of the fixed handles 3 pivotally connect with the linking-up arms 17 of the body 1 to press and pull freely the linking-up arms 17. The eccentric wheel 34 of the fixed handles 3 is disposed on the contacting surfaces 14 of the extending arms 12 of the body 1 for conveniently pressing and pulling the fixed handles 3 to the fixed sections 341. The released sections 342 of the eccentric wheels 34 selectively connect with the contacting surface 14 of the body 1 so as to link the elastic hooking arm 15 to swing inwardly and outwardly while the linking-up arms 17 are driven.

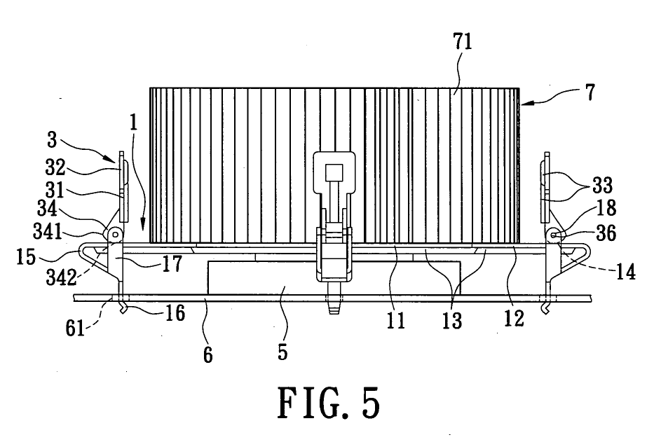

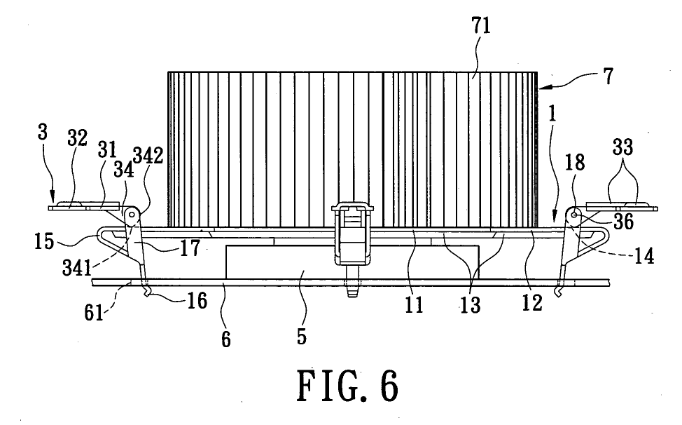

Reference is made to FIG. 5 and FIG. 6. A radiator 7 is disposed on the body 1, the radiator 7 and the body 1 are rigidly disposed on a surface of the central processing unit 5. The radiator 7 is made of metal materials like aluminum or copper with good heat conductively and the radiator 7 has a plurality of heat sinks 71 for increasing the heat-dissipating area thereof. The radiator 7 can be made in various ways, such as, for example, extrusion, die casting, or hot rolling. The radiator 7 is disposed on the central processing unit 5 and a bottom surface of the radiator 7 connects with a top surface of the central processing unit 5 to pass the heat produced from the central processing unit 5 to the radiator 7 so as to dissipate heat form the central processing unit 5 via the radiator 7. The central processing unit 5 on a motherboard 6 and a plurality of hooking holes 61 correspond to the elastic hooking arms 15 disposed on the motherboard 6.

If the fastening device is used as a fixing device, the elastic hooking arms 15 of the body 1 correspondingly match the hooking holes 61 of the motherboard 6 then the fixed handles 3 are pulled to connect correspondingly the fixed sections 341 of the eccentric wheels 34 of the fixed handles 3 with the contacting surfaces 14 of the extending arms 12 of the body 1. The eccentric wheels 34 thus touch the contacting surfaces 14 to drive the linking-up arms 17 to swing inwardly the elastic hooking arms 15 via the pivots 36 so as to buckle firmly the hooking portions 16 of the bottom of the elastic hooking arms 15 on the hooking holes 61 of the motherboard 6 (shown in FIG. 6). Furthermore, the radiator 7 and the body 1 are rigidly disposed on the surface of the central processing unit 5 to dispose firmly the central processing unit 5 on the motherboard 6.

If the fastening device is released, it is only necessary to pull reversely the fixed handles 3 to make the released sections 342 of the eccentric wheels 34 of the fixed handles 3 connect with the contacting surfaces 14 of the extending arms 12 of the body 1 so that the eccentric wheels 34 touch the contacting surfaces 14 to drive the linking-up arms 17 to swing outwardly the elastic hooking arms 15 via the pivots 36. The hooking portions 16 of the bottom of the elastic hooking arms 15 on the hooking holes 61 of the motherboard 6 are thus released (shown in FIG. 5).

The bucking device of the present invention is composed of a body 1 and four fixed handles 3. The body 1 is an integrated structure with a frame 11, extending arms 12, elastic hooking arms 15, and linking-up arms 17. Because these components are integrated with the body 1, these components need not be mutually combined. Besides, it is easy to fabricate so as to effectively reduce the production costs since the structure is simple and has few parts. The body 1 has an integrated design and is thus a stable structure that the extending arms 12 and the elastic hooking arms 15 do not shake. Because the elastic hooking arms 15 of the body 1 are easily correspondingly put into the hooking holes 61 of the motherboard 6, they cannot be misplaced. Moreover, the fixed handles 3 control the elastic hooking arms 15 to be hooked on the motherboard 6 without damaging the motherboard 6 in spite of the strong hooking strength.

Moreover, the linking-up arms 17 can be designed to various angles to control the hooking strength with different elasticity.

Although the present invention has been described with reference to the preferred embodiment thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A fastening device II, comprising:
a body with a frame having four corners, wherein each of the corners of the frame respectively extends a extending arm, the extending arm has a top with a contacting surface and one end of the extending arm extends a elastic hooking arm, and two sides of the elastic hooking arm connect with linking-up arms; and
four fixed handles respectively including a handle body, wherein one end of the handle body connects with a pressing arm and another end of the handle body connects with an eccentric wheel, the eccentric wheels of the fixed handles pivotally connect with the linking-up arms of the body, one of the eccentric wheels respectively forms a fixed section and a released section on the edge thereof, and the fixed section and the released section selectively connect with the contacting surface of the body.

2. A fastening device II as in claim 1, wherein the body has a rectangular frame.

3. A fastening device II as claim 1, wherein a frame of the body and an edge of the extending arms form strengthening portions.

4. A fastening device II as claim 1, wherein each bottom of the elastic hooking arms of the body respectively forms a hook-typed hooking portion.

5. A fastening device II as claim 1, wherein each of the linking-up arms of the body respectively drills a pivoted hole, each of the eccentric wheels of the fixed handles respectively drills a shaft hole, and the shaft holes of the fixed handles pivotally connect with the pivoted holes of the linking-up arms of the body via a plurality of pivots.

6. A fastening device II as claim 5, wherein a distance from the fixed section to the shaft hole of the eccentric wheel of the fixed handle is greater than a distance from the released section to the shaft hole thereof.

7. A fastening device II as claim 1, wherein the handle body and the pressing arm have middles forming a strengthening portion.

8. A fastening device II as claim 1, wherein the body is disposed on a central processing unit and the central processing unit is disposed on a motherboard, and a plurality of hooking holes corresponding to the elastic hooking arms disposed on the motherboard and the elastic hooking arms fixedly hook the hooking holes on the motherboard.

9. A fastening device II as claim 1, comprising a radiator disposed on the body, wherein the radiator has a plurality of heat sinks.
